(19) United States
(12) Patent Application Publication
(10) Pub. No.: US 2013/0145918 A1
(43) Pub. Date: Jun. 13, 2013

(54) TRENCH SCRIBING APPARATUS AND TRENCH SCRIBING METHOD

(71) Applicants: Yan-Ying Tsai, Kaohsiung City (TW); Tung-Po Hsieh, Taipei City (TW); Chern-Lin Chen, New Taipei City (TW)

(72) Inventors: Yan-Ying Tsai, Kaohsiung City (TW); Tung-Po Hsieh, Taipei City (TW); Chern-Lin Chen, New Taipei City (TW)

(73) Assignee: INDUSTRIAL TECHNOLOGY RESEARCH INSTITUTE, Hsinchu (TW)

(21) Appl. No.: 13/421,845

(22) Filed: Mar. 15, 2012

(30) Foreign Application Priority Data
Dec. 7, 2011 (TW) 100145096

(51) Int. Cl. B26D 3/06

(52) U.S. Cl. 83/875

(57) ABSTRACT

A trench scribing apparatus and a trench scribing method adapted to scribe a trench on a substrate are provided. The apparatus includes a platen, a guide rod structure, a supporting carrier and a pin device. The guide rod structure is disposed above the platen. The supporting carrier is fixed on the guide rod structure, and the substrate is disposed on the supporting carrier. The pin device is disposed above the supporting carrier and includes a pin holder and a plurality of pins fastened on the pin holder, and the pins are arranged into at least one straight line.

### CROSS-REFERENCE TO RELATED APPLICATION

This application claims the priority benefit of Taiwan application serial no. 100145096, filed Dec. 7, 2011. The entirety of the above-mentioned patent application is hereby incorporated by reference herein and made a part of this specification.

### TECHNICAL FIELD

The disclosure relates to a trench scribing apparatus and a trench scribing method.

### BACKGROUND

Generally, trenches are adapted to isolate or insulate devices, and thus locations of the trenches and forming methods of the trenches may affect characteristics of device modules. For example, in a conventional copper-indium-gallium-selenium (CIGS) solar cell module, trenches in the CIGS solar cell module are usually formed with a laser cutting process or a mechanical cutting process. However, the high energy of the laser cutting process may influence the film property. In addition, if the trenches are formed with conventional mechanical cutting process, the trenches do not have good smoothness, and the life-span of the conventional mechanical cutting tool is not long enough.

### SUMMARY

A trench scribing apparatus adapted to scribe a trench on a substrate is provided. The apparatus includes a platen, a guide rod structure, a supporting carrier and a pin device. The guide rod structure is disposed above the platen. The supporting carrier is fixed on the guide rod structure, and the substrate is disposed on the supporting carrier. The first pin device is disposed above the supporting carrier and includes a first pin holder and a plurality of first pins fastened on the first pin holder, and the first pins are arranged into at least one straight line.

A method of scribing a trench is provided. The method includes providing a trench scribing apparatus which includes a first pin device. The first pin device comprises a first pin holder and a plurality of first pins fastened on the first pin holder, and the first pins are arranged into at least one straight line. A first scribing process is performed. The first scribing process includes moving the first pin device along a first direction so that each of the first pins scribes a first sub-trench on a substrate, and the first sub-trenches scribed from the first pins are connected to one another to form a first trench.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic diagram illustrating a trench scribing apparatus according to an exemplary embodiment.

FIG. 2A and FIG. 2B are schematic diagrams illustrating pin devices of the trench scribing apparatus according to an exemplary embodiment.

FIG. 3A to FIG. 3B are schematic diagrams showing a trench scribing method according to an exemplary embodiment.

FIG. 4 is a schematic diagram illustrating a pin device of the trench scribing apparatus according to another exemplary embodiment.

FIG. 5A to FIG. 5B are schematic diagrams showing a trench scribing method according to another exemplary embodiment.

FIG. 6 a schematic diagram showing the trench position formed with the method of FIG. 5A to FIG. 5B.

FIG. 7A to FIG. 7C are schematic diagrams showing a method of forming a solar cell module according to an exemplary embodiment.

FIG. 8A to FIG. 8F are pictures showing trenches formed with the trench scribing apparatus according to an exemplary embodiment.

FIG. 9 a schematic diagram showing a distribution of widths of trench I and the trench II according to an exemplary embodiment.

### DETAILED DESCRIPTION OF DISCLOSED EMBODIMENTS

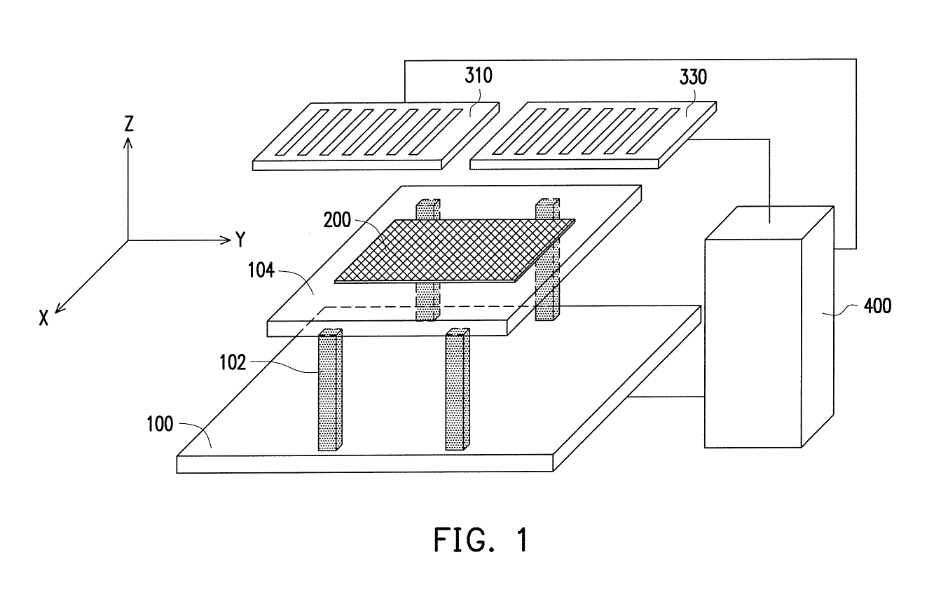

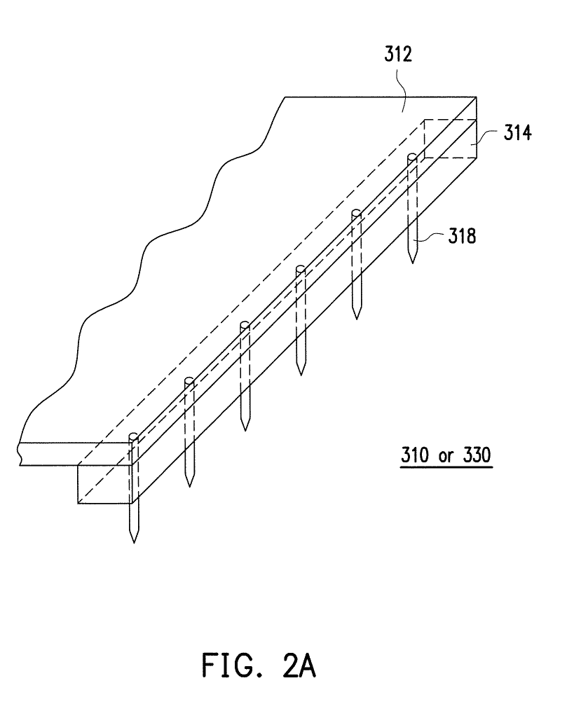

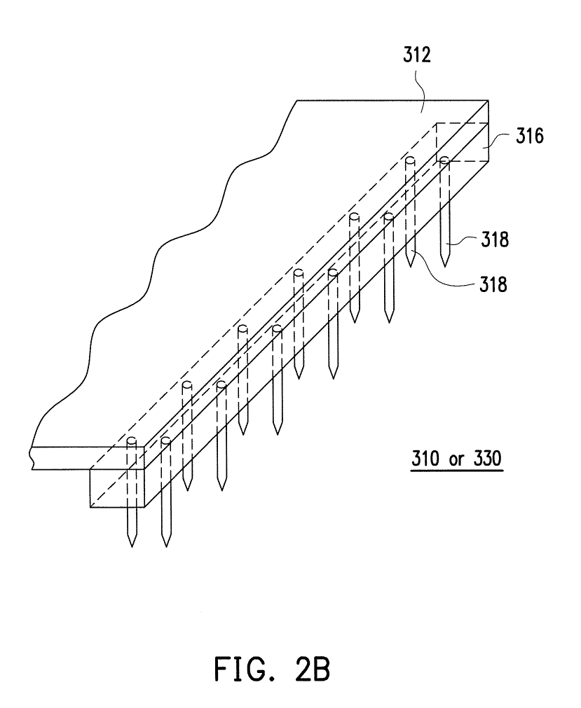

FIG. 1 is a schematic diagram illustrating a trench scribing apparatus according to an exemplary embodiment. FIG. 2A and FIG. 2B are schematic diagrams illustrating pin devices of the trench scribing apparatus according to an exemplary embodiment. Referring to FIG. 1, FIG. 2A and FIG. 2B, the trench scribing apparatus is adapted to scribe a trench on a substrate 200. The apparatus includes a platen 100, a guide rod structure 102, a supporting carrier 104 and a first pin device 310. According to an exemplary embodiment, the trench scribing apparatus further comprises a controller 400 and a second pin device 330. The substrate 100 may be an insulating substrate, a conductive substrate, a substrate having an insulator thereon, or a substrate having a conductive film thereon.

The guide rod structure 102 is disposed above the platen 100. The guide rod structure 102 above the platen 100 can move up and move down along Z direction.

The supporting carrier 104 is fixed on the guide rod structure 102 to carrier the substrate 200. Herein, the supporting carrier 104 may further comprise a fixing structure so as to fix the substrate 200 on the supporting carrier 104. Since the substrate 200 is fixed on the supporting carrier 104, the substrate 200 on the supporting carrier 104 can be positioned at a predetermined level through the move of the guide rod structure 102 along Z direction.

The first pin device 310 is disposed above the supporting carrier 104. The first pin device 310 includes a pin holder 314 and a plurality of pins 318 fastened on the pin holder 314, and the pins 318 are arranged into at least one straight line, as shown in FIG. 2A. In order to clearly describe the exemplary embodiment, one row of pins 318 is shown in FIG. 2A. As a matter of fact, the first pin device 310 may include a plurality of rows of pins 318, as shown in FIG. 2B, the first pin device 310 includes two rows of pins 318. Namely, the pins 318 fastened on the pin holder 316 can be arranged into any type of array. If the first pin device 310 includes a plurality of rows of pins 318, the pin holder 316 is designed to a plate structure, such that several rows of pins 318 are fastened on the pin holder 316. In addition, the pin holder 316 may further be fixed on a moving device 312. When the moving device 312 is moved, the pin holder 316 and the pins 318 are moved accordingly.

In the first pin device 310, two adjacent pins 318 of the each row of pins 318 have a space therebetween. The pins 318 comprise knife pins, acicular pins, roll pins, or taper pins. Moreover, a gas cleaning device (not shown) may also be further disposed on the pin holder (314 or 316) above the pins 318. The gas cleaning device may eject a gas toward the pins 318, so as to clean residuals after the pins 318 scribing the substrate 200.

In addition, the trench scribing apparatus further comprises a second pin device 330. The second pin device 330 is as shown in FIG. 2A or FIG. 2B and comprises the pin holder (314 or 316) and the pins 318 fastened on the pin holder (314 or 316).

It is noted that the trench scribing apparatus is equipped with two pin devices which is taken as an example for descriptions. The disclosure does not limit the number of pin devices in the trench scribing apparatus. Namely, in anther exemplary embodiment, the trench scribing apparatus may be equipped with one pin device or three or more pin devices. In addition, the number of the pins 318 in the first pin device 310 and the number of the pins 318 in the second pin device 330 may be the same or different. The material, length, hardness, space or other conditions of the pins 318 in the first pin device 310 and the material, length, hardness, space or other conditions of the pins 318 in the second pin device 330 may be the same or different according to the requirements of actual applications.

Referring to FIG, 1, the controller 400 is electrically connected to the first pin device 310, the second pin device 330, the platen 100 and the guide rod structure 102, so as to control the relative position between the first pin device 310(the second pin device 330) and the supporting carrier 104.

A trench scribing method with the foregoing trench scribing apparatus is described as following.

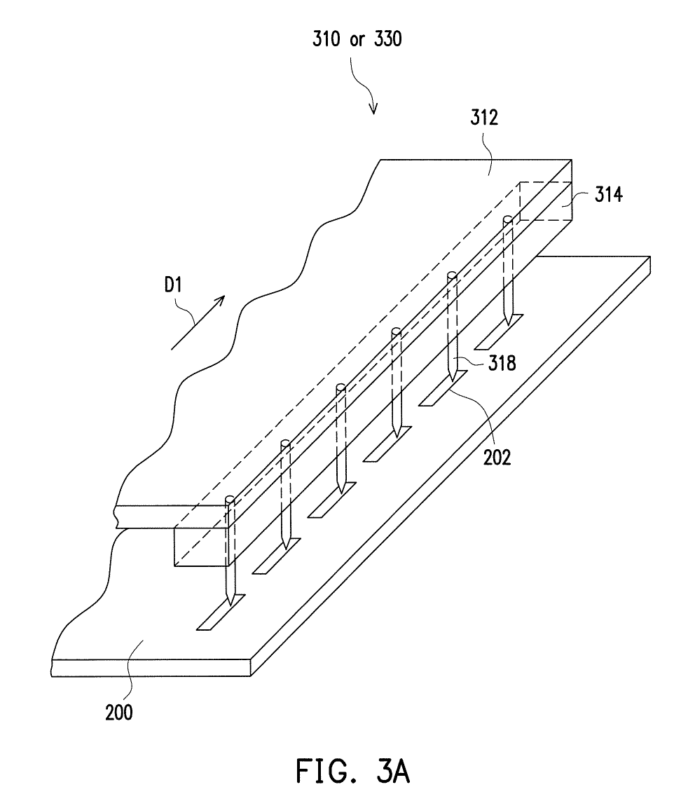

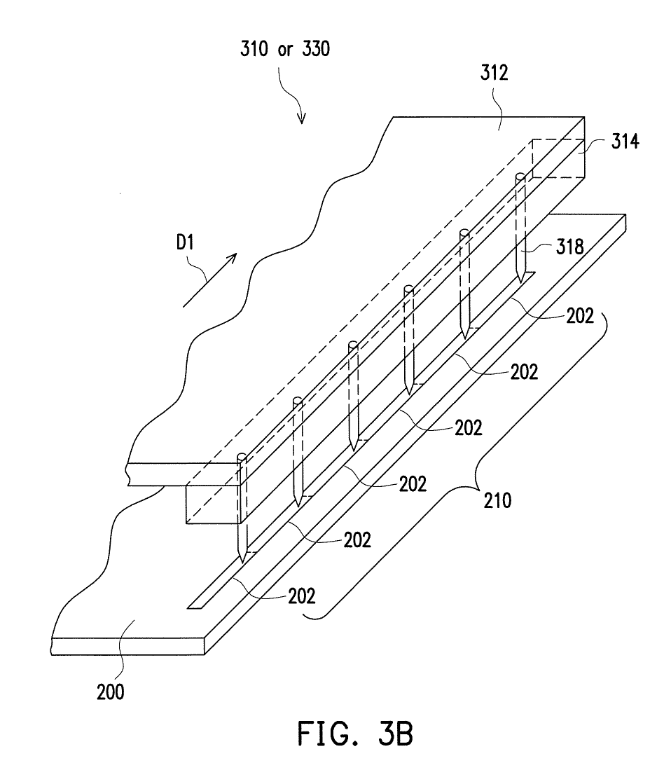

FIG. 3A to FIG. 3B are schematic diagrams showing a trench scribing method according to an exemplary embodiment. In order to clearly describe the exemplary embodiment, FIG. 3A and FIG. 3B only show the substrate 200 and the first pin device 310 (or the second pin device 330).

Referring to FIG. 1 and FIG. 3A, the first pin device 310 and the substrate 200 on the supporting carrier 104 are orientated in X direction and Y direction, and then the first pin device 310 and the substrate 200 on the supporting carrier 104 are orientated in Z direction through the guide rod structure 102. For detail, the controller 400 controls the first pin device 310 to move in the X direction and the Y direction, such that the first pin device 310 is located corresponding to a position where a trench is predetermined formed on the substrate 200. Moreover, the controller 400 controls the guide rod structure 102 to move in the Z direction, such that the pins 318 of the first pin device 310 are in contact with the surface of the substrate 200.

After that, a first scribing process is performed, as shown in FIG. 3A. The first scribing process comprises moving the first pin device 310 along a first direction D1 so that each of the pins 318 of the first pin device 310 scribes a first sub-trench 202 on the substrate 200. During the first scribing process, a gas cleaning step is further performed with the gas cleaning device (not shown) so as to clean residuals after the pins 318 of the first pin device 310 scribing the substrate 200. After performing the first scribing process, the first sub-trenches 202 scribed from the pins 318 of the first pin device 310 are connected to one another to form a first trench 210, as shown in FIG. 3B. The width of the first sub-trench 202 (the first trench 210) ranges from 1 μm to 1000 μm, which is relative to the size of the pins 318.

It is noted that, FIG, 3A and FIG. 3B only show one first trench 210 for illustration. As a matter of fact, if the first pin device 310 includes a plurality of rows of pins 318, a plurality of first trenches 210 parallel to each other are formed on the substrate 200 after performing the first scribing process. In particular, each of the first trenches 210 is formed from a plurality of first sub-trenches 202 connected to one another.

After the first scribing process is performed with the first pin device 310, the controller 400 controls the first pin device 310 to depart from the substrate 200, and then the controller 400 controls the second pin device 330 to close the substrate 200. Similarly, the controller 400 controls the second pin device 330 to move in the X direction and the Y direction, such that the second pin device 330 is located corresponding to a position where a trench is predetermined formed on the substrate 200. Moreover, the controller 400 controls the guide rod structure 102 to move in the Z direction, such that the second pin device 330 is in contact with the surface of the substrate 200.

After that, a second scribing process is performed with the second pin device 330. The second scribing process is similar to the first scribing process. The second scribing process comprises moving the second pin device 330 along a second direction so that each of the pins 318 of the second pin device 330 scribes a second sub-trench (not shown) on the substrate 200, and the second sub-trenches (not shown) scribed from the second pin device 330 are connected to one another to form a second trench (not shown). During the second scribing process, a gas cleaning step is further performed with the gas cleaning device (not shown) so as to clean residuals after the pins 318 scribing the substrate 200. Similarly, if the second pin device 330 includes a plurality of rows of pins 318, a plurality of second trenches (not shown) parallel to each other are formed on the substrate 200 after performing the second scribing process.

It is noted that in the foregoing exemplary embodiment, the first pin device 310 and the second pin device 330 scribe the trenches on the substrate 200, but the disclosure does not limit to the exemplary embodiment. According to another exemplary embodiment, the first pin device 310 scribes the trenches on the substrate, and the second pin device 330 scribe the trenches on a film layer on the substrate.

In addition, in the exemplary embodiment, the first trenches and the second trenches formed by the trench scribing method is taken as an example for descriptions. According to anther exemplary embodiment, a third trench scribing process or more trench scribing processes may also be performed with the first pin device 310 or the second pin device 330.

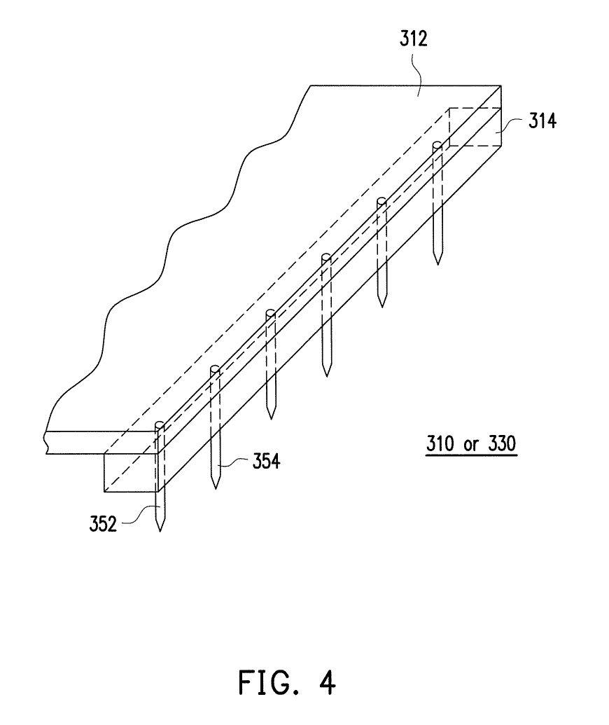

FIG. 4 is a schematic diagram illustrating a pin device of the trench scribing apparatus according to another exemplary embodiment. Referring to FIG. 4, the exemplary embodiment of FIG. 4 is similar to the embodiment of FIG. 2A, so that the same devices are denoted by the same symbols, and descriptions thereof are not repeated. The difference between the exemplary embodiment of FIG. 4 and the embodiment of FIG. 2A lies in that the pin device not only includes the pin holder but also includes at least one main pin 354 and at least one auxiliary pin 352 fastened on the pin holder 314. The main pin 354 and the auxiliary pin 352 are arranged alternatively. In an exemplary embodiment, a hardness of the main pin 354 and a hardness of the auxiliary pin 352 are different, for example, the hardness of the main pin 354 is larger than the hardness of the auxiliary pin 352. In another exemplary embodiment, a length of the main pin 354 and a length of the auxiliary pin 352 are different, for instance, the length of the main pin 354 is larger than the length of the auxiliary pin 352.

A trench scribing method with the pin device of FIG. 4 is described as following.

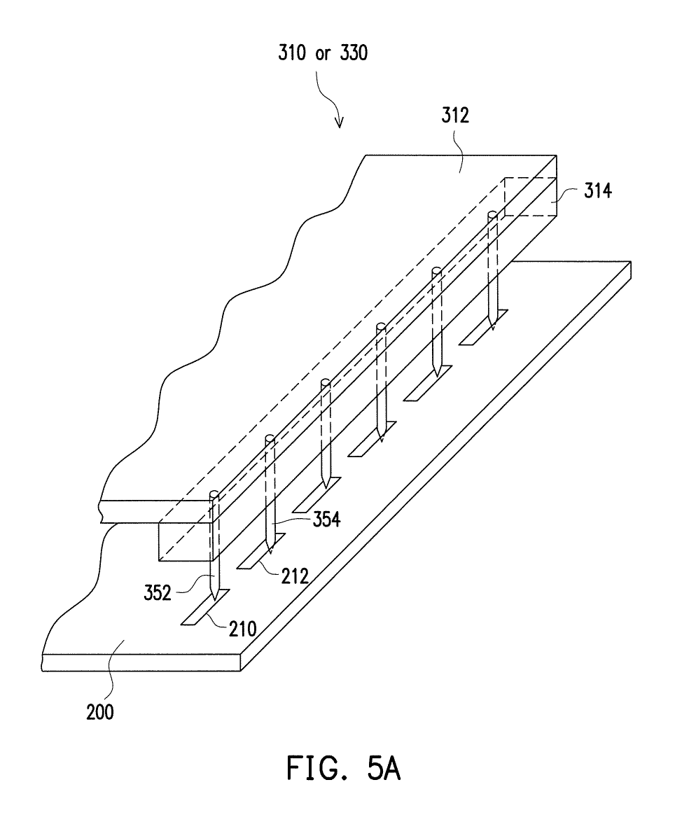

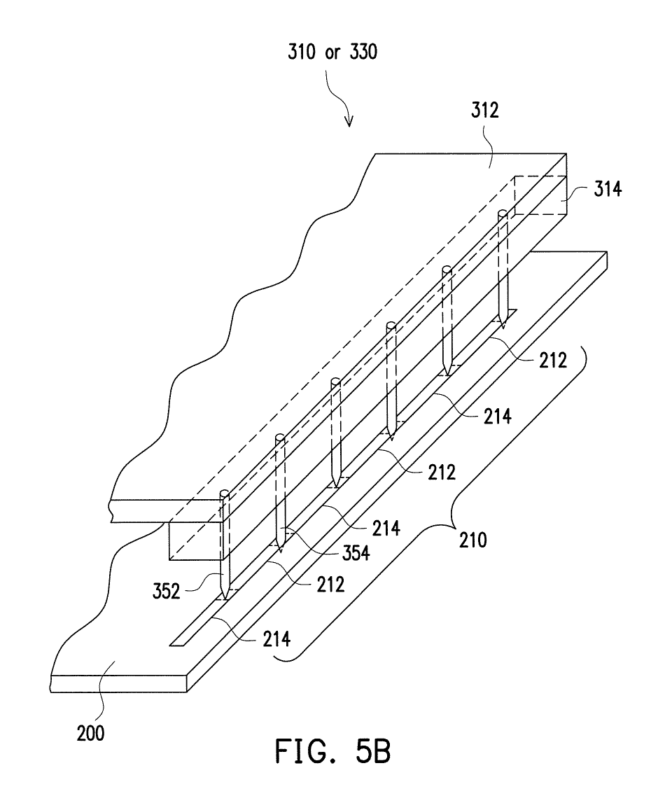

FIG. 5A to FIG. 5B are schematic diagrams showing a trench scribing method according to an exemplary embodiment. In order to clearly describe the exemplary embodiment, FIG. 5A and FIG. 5B only show the substrate 200 and the first pin device 310 (or the second pin device 330).

Referring to FIG. 1 and FIG. 5A, the first pin device 310 and the substrate 200 are orientated in X direction, Y direction and Z direction. The method of orientating the first pin device 310 and the substrate 200 in the X direction, Y direction and Z direction is the same or similar to that described in FIG. 3A and FIG. 3B.

After that, a first scribing process is performed, so that each of the auxiliary pin 352 of the first pin device 310 scribes a auxiliary sub-trench 214 on the substrate 200 and each of the main pin 354 of the first pin device 310 scribes a main sub-trench 212 on the substrate 200. In the exemplary embodiment, the length of the main pin 354 is larger than the length of the auxiliary pin 352, and thereby a depth of main sub-trench 212 is larger than a depth of the auxiliary sub-trench 214. After the first scribing process is performed, the main sub-trench 212 and the auxiliary sub-trench 214 are partially overlapped (an overlapping region between the main sub-trench 212 and auxiliary sub-trench 214 is 230) so as to form a complete trench 210.

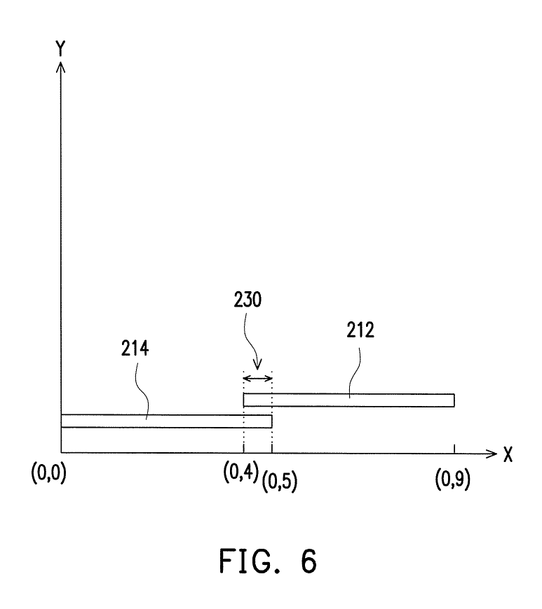

The main sub-trench 212 and auxiliary sub-trench 214 are partially overlapped as shown in FIG. 6. Referring to FIG. 6, for instance, the auxiliary pin 352 scribes the auxiliary sub-trench 214 from the coordinate (0, 0) and the main pin 354 scribes the main sub-trench 212 from the coordinate (0, 4). The auxiliary pin 352 scribes the auxiliary sub-trench 214 from the coordinate (0, 0) to the coordinate (0, 5), so as to form the auxiliary sub-trench 214. That is, two ends of the auxiliary sub-trench 214 are located at the coordinate (0, 0) and the coordinate (0, 5). In addition, the main pin 354 scribes the main sub-trench 212 from the coordinate (0, 4) to the coordinate (0, 9), so as to form the main sub-trench 212. That is, two ends of the main sub-trench 212 are located at the coordinate (0, 4) and the coordinate (0, 9). Namely, the region between the coordinate (0, 4) and the coordinate (0, 9) is the overlapping region 230 between the main sub-trench 212 and auxiliary sub-trench 214.

The first pin device 310 in the trench scribing method of FIG. 5A and FIG. 5B has the main pin 354 and the auxiliary pin 352. If the substrate 200 is a harder substrate, cracks are not easily formed when the substrate 200 is scribed by this first pin device 310, and the scribed trenches on the substrate 200 are smoother.

Furthermore, after performing the first scribing process, a second scribing process with the second pin device 330 may further be performed. Herein, the second scribing process may introduce the steps as shown in FIG. 3A to FIG. 3B (that is, the pins of the pin device are the same), or introduce the steps as shown in FIG. 5A to FIG. 5B (that is, the pins of the pin device includes the main pins and the auxiliary pins).

The trench scribing apparatus and the trench scribing method can be applied to manufacturing processes of electronic devices or semiconductor devices. In the following description, the trench scribing apparatus and the trench scribing method are applied to a method of manufacturing a solar cell, which are not limited by the disclosure.

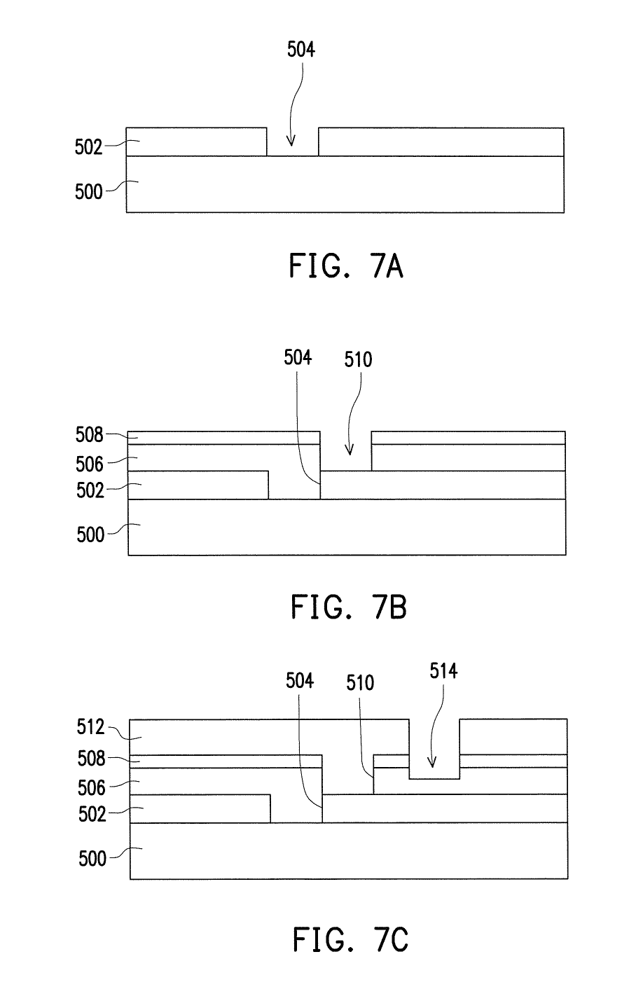

FIG. 7A to FIG. 7C are schematic diagrams showing a method of forming a solar cell module according to an exemplary embodiment. As shown in FIG. 7A, a metal layer 502 is formed on a substrate 500. A first trench scribing process is performed to the first metal layer 502 with the trench scribing apparatus of FIG. 1, so as to form a plurality of first trenches 504 (only one trench is shown as an example for descriptions). According to an exemplary embodiment, the metal layer 502 comprises molybdenum (Mo) or any other appropriate electrode material.

A semiconductor layer 506 and a buffer layer 508 are foamed on the substrate 500 to cover the metal layer 502 and the first trench 504. Next, a second trench scribing process is performed to the semiconductor layer 506 and the buffer layer 508 with the trench scribing apparatus of FIG. 1, so as to form a plurality of second trenches 510 (only one trench is shown as an example for descriptions), as shown in FIG. 7B. The semiconductor layer 506, for example, comprises copper-indium-gallium-selenium (CuInGaSe₂) or any other appropriate semiconductor material suitable for solar cells. The buffer layer 508, for example, comprises cadmium sulfide (CdS) or any other appropriate buffer material which matching with the semiconductor layer 506.

A transparent conductive layer 512 is formed on the substrate 500 to cover the buffer layer 508 and the second trench 510. A third trench scribing process is performed to the transparent conductive layer 512 with the trench scribing apparatus of FIG. 1, so as to form a plurality of third trenches 514 (only one trench is shown as an example for descriptions), as shown in FIG. 7C. The transparent conductive layer, for example, comprises zinc oxide (ZnO) or any other appropriate transparent electrode material.

The solar cell module formed with the steps shown in FIG. 7A to FIG, 7C is a CIGS solar cell module, but the present disclosure did not limit to the exemplary embodiment. In the CIGS solar cell module, the widths of the first trench 504, the second trench 510 and the third trench 514 range from 1 um to 1000 um. A horizontal distance between the first trench 504 and the second trench 510 ranges from 1 um to 100000 um. A horizontal distance between the second trench 510 and the third trench 514 ranges from 1 um to 100000 um.

In view of the previous exemplary embodiments, the pin device of the trench scribing apparatus comprises a pin holder and a plurality of pins fastened on the pin holder, and the pins are arranged into at least one straight line. When a scribing process is performed with the trench scribing apparatus, each of the pins scribes a sub-trench on a substrate, and after the scribing process is performing, the sub-trenches are connected to one another to form a complete trench. Since a single trench is formed by a plurality of pins arranged into a straight line, the trench scribing method is faster than conventional methods. In addition, because the scribe length of each pin is not long, scribed residues can be avoided during the trench scribing process and thereby the scribed trench is smoother.

### EXAMPLE

In the example, the pins of the pin device are arranged into an array of 2×3. The pins arranged into the array of 2×3 of the pin device may scribe two trenches (trench I and trench II), and each trench (trench I and trench II) are scribed from 3 pins. The pins are stainless steel pins and each pin is moved about 0.45 cm. In addition, each trench (trench I and trench II) has a total length about 1.2 cm and has an average width about 117 um. After the pin device scribes the trenches, a gas cleaning process is performed to clean residues on surfaces of the pins.

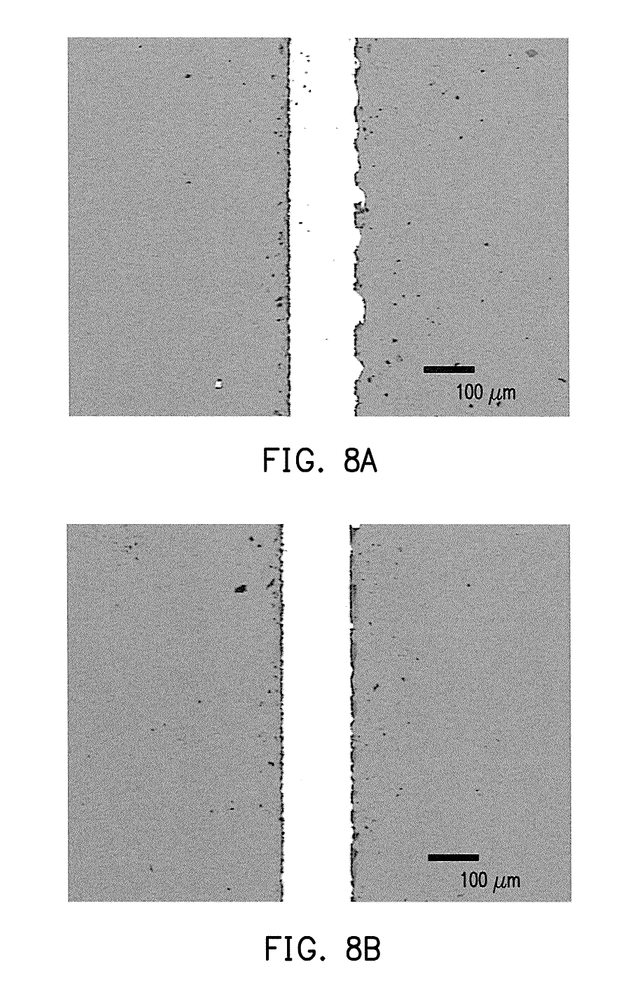

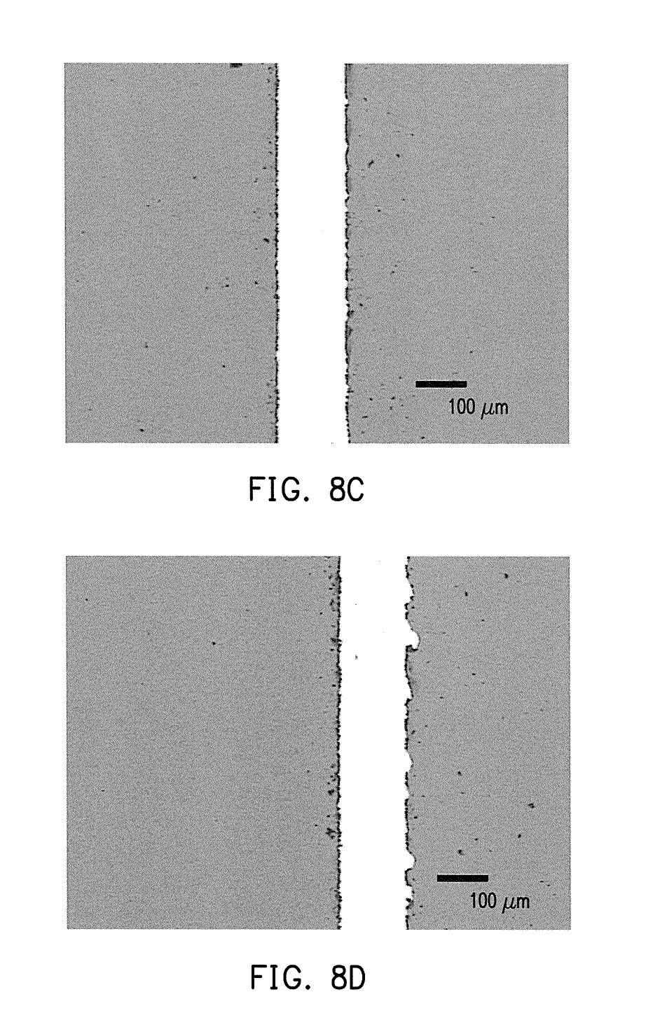

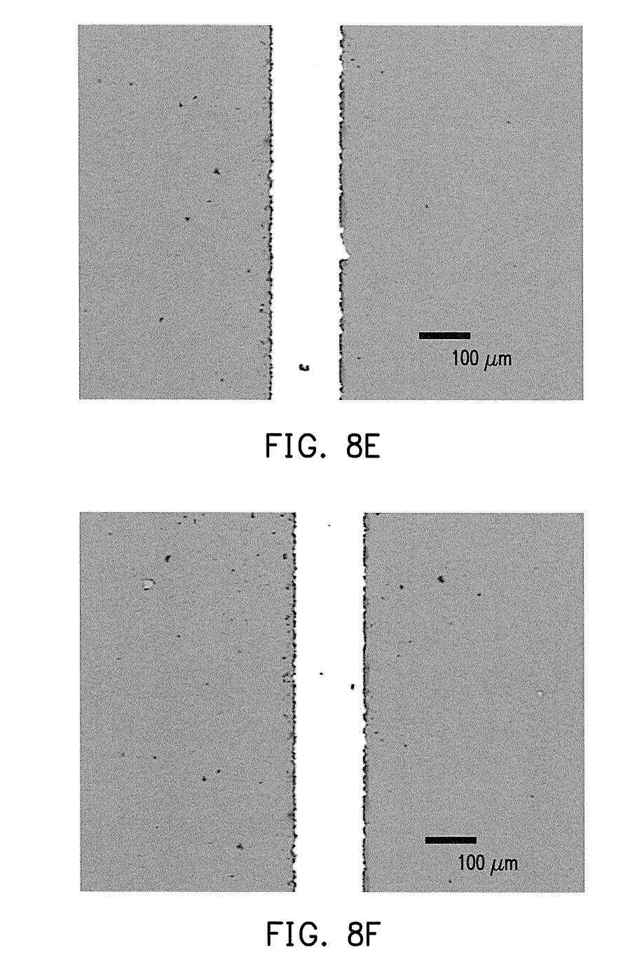

FIG. 8A to FIG. 8F are pictures showing trenches formed with the trench scribing apparatus according to an exemplary embodiment. FIG. 8A to FIG. 8C show trench I, in which FIG. 8A shows the sub-trench scribed by the first pin, and FIG. 8B and FIG. 8C respectively show the sub-trenches scribed by the second pin and the third pin. FIG. 8D to FIG. 8F show trench II, in which FIG. 8D shows the sub-trench scribed by the first pin, and FIG. 8E and FIG. 8F respectively show the sub-trenches scribed by the second pin and the third pin. As shown in FIG. 8A to FIG. 8F, trench I and trench II both have smooth edges. In addition, a connection portion between the first pin and the second pin (as shown at the front end of the trench in FIG, 8B and FIG. 8E) does not crack or burst, and thus the width at connection portion is not increased. FIG. 8C and FIG. 8F (the front ends of the second pin and the third pin) also show the similar conditions or results. Therefore, the example proves that forming a single trench with a plurality of pins is practicable. In addition, the inside of the trench in the example present a shiny metal electrode, that means the scribing residue is not remained in the trench and two films beside the trench are not connected to each other.

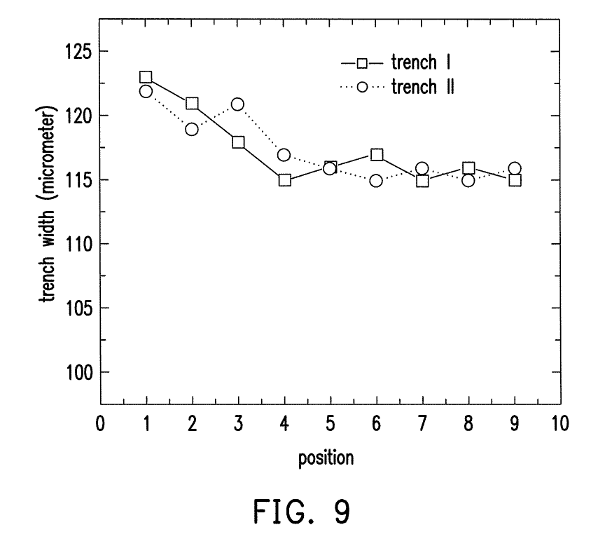

FIG. 9 a schematic diagram showing a distribution of widths of trench I and the trench II according to an exemplary embodiment. The trench width is measured with a α-step film thickness instrument. The largest width of trench I is 123.2 um, the smallest width of trench I is 114.8 um, an average width of trench I is 117.3, and a standard variation is 2.71. The largest width of trench II is 122.3 um, the smallest width of trench II is 115.7 um, an average width of trench II is 117.4, and a standard variation is 2.46.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A trench scribing apparatus adapted to scribe a trench on a substrate, the apparatus comprising:
a platen;
a guide rod structure, disposed above the platen;
a supporting carrier, fixed on the guide rod structure, and the substrate is disposed on the supporting carrier, and
a first pin device, disposed above the supporting carrier and comprising a first pin holder and a plurality of first pins fastened on the first pin holder, wherein the first pins are arranged into at least one straight line.

2. The trench scribing apparatus as claimed in claim 1, wherein the first pins fastened on the first pin holder are arranged into an array.

3. The trench scribing apparatus as claimed in claim 1, wherein the first pins comprise at least one main pin and at least one auxiliary pin.

4. The trench scribing apparatus as claimed in claim 3, wherein a hardness of the main pin and a hardness of the auxiliary pin are different, or a length of the main pin and a length of the auxiliary pin are different.

5. The trench scribing apparatus as claimed in claim 1, wherein the first pins comprise knife pins, acicular pins, roll pins, or taper pins.

6. The trench scribing apparatus as claimed in claim 1, further comprising a second pin device, disposed above the supporting carrier and comprising a second pin holder and a plurality of second pins fastened on the second pin holder, wherein the second pins are arranged into at least one straight line.

7. The trench scribing apparatus as claimed in claim 6, wherein the second pins fastened on the second pin holder are arranged into an array.

8. The trench scribing apparatus as claimed in claim 6, wherein the second pins comprise at least one main pin and at least one auxiliary pin.

9. The trench scribing apparatus as claimed in claim 8, wherein a hardness of the main pin and a hardness of the auxiliary pin are different, or a length of the main pin and a length of the auxiliary pin are different.

10. The trench scribing apparatus as claimed in claim 6, wherein the second pins comprise knife pins, acicular pins, roll pins, or taper pins.

11. A method of scribing a trench, comprising:
providing a trench scribing apparatus comprising a first pin device, wherein the first pin device comprises a first pin holder and a plurality of first pins fastened on the first pin holder, and the first pins are arranged into at least one straight line; and
performing a first scribing process, the first scribing process comprising moving the first pin device along a first direction so that each of the first pins scribes a first sub-trench on a substrate, wherein the first sub-trenches scribed from the first pines are connected to one another to form a first trench.

12. The method as claimed in claim 11, wherein the first pins fastened on the first pin holder are arranged into an array, and
the first sub-trenches scribed from the first pins on the substrate are connected to form a plurality of first trenches parallel to each other after performing the first scribing process.

13. The method as claimed in claim 11, wherein the first pins comprise at least one main pin and at least one auxiliary pin, and
the main pin scribes a main sub-trench on the substrate and the auxiliary pin scribes a auxiliary sub-trench on the substrate when performing the first scribing process, and the auxiliary sub-trench partially overlaps with the main sub-trench.

14. The method as claimed in claim 13, wherein a depth of the main sub-trench is larger than a depth of the auxiliary sub-trench.

15. The method as claimed in claim 11, wherein the trench scribing apparatus further comprises a second pin device comprising a second pin holder and a plurality of second pins fastened on the second pin holder, the second pins are arranged into at least one straight line, and the method further comprises:
performing a second scribing process after performing the first scribing process, the second scribing process comprising moving the second pin device along a second direction so that each of the second pins scribes a second sub-trench on the substrate, wherein the second sub-trenches scribed from the second pins are connected to one another to form a second trench.

16. The method as claimed in claim 15, wherein the second pins fastened on the second pin holder are arranged into an array, and
the second sub-trenches scribed from the second pines on the substrate are connected to form a plurality of second trenches parallel to each other after performing the second scribing process.

17. The method as claimed in claim 15, wherein the second pins comprise at least one main pin and at least one auxiliary pin, and
the main pin scribes a main sub-trench on the substrate and the auxiliary pin scribes a auxiliary sub-trench on the substrate when performing the second scribing process, and the auxiliary sub-trench partially overlaps with the main sub-trench.

18. The method as claimed in claim 17, wherein a depth of the main sub-trench is larger than a depth of the auxiliary sub-trench.

19. The method as claimed in claim 11, wherein the trench scribing apparatus further comprises a platen, a guide rod structure disposed above the platen, and a supporting carrier fixed on the guide rod structure, the substrate is disposed on the supporting carrier, and the method further comprises:
orientating the supporting carrier and the first pin device in X direction, Y direction and Z direction through the guide rod structure before performing the first scribing process.
